(19) United States
(12) Patent Application Publication
(10) Pub. No.: US 2023/0070350 A1
(43) Pub. Date: Mar. 9, 2023

(54) ACOUSTIC WAVE DEVICE WITH FLOATING INTERDIGITAL TRANSDUCER

(71) Applicant: SKYWORKS SOLUTIONS, INC., Irvine, CA (US)

(72) Inventor: Rei Goto, Osaka-Shi (JP)

(21) Appl. No.: 17/929,376

(22) Filed: Sep. 2, 2022

Related U.S. Application Data
(60) Provisional application No. 63/241,669, filed on Sep. 8, 2021.

(51) Int. Cl. H03H 9/02; H03H 9/145; H03H 9/64

(52) U.S. Cl. CPC H03H 9/02834; H03H 9/6483; H03H 9/14544

(57) ABSTRACT

An acoustic wave device, a radio frequency filter and an electronics module are provided. The acoustic wave device comprises a piezoelectric substrate, a temperature compensation layer disposed on the piezoelectric substrate, and an interdigital transducer embedded within the temperature compensation layer and spatially separated from the piezoelectric substrate. The interdigital transducer is configured to generate an acoustic wave in response to an electrical signal. A passivation layer is disposed on the temperature compensation layer. The acoustic wave device can be used in wide passband applications, and has an excellent temperature coefficient, small size, and a clean response.

### CROSS-REFERENCE TO RELATED APPLICATIONS

This application claims priority under 35 U.S.C. § 119(e) to U.S. Provisional Pat. Application Serial No. 63/241,669, titled “ACOUSTIC WAVE DEVICE WITH FLOATING INTERDIGITAL TRANSDUCER,” filed Sep. 8, 2021, the entire content of which is incorporated herein by reference for all purposes.

### BACKGROUND

### Field

Aspects and embodiments disclosed herein relate to an acoustic wave device, a radio frequency filter and an electronics module. In particular, aspects and embodiments disclosed herein relate to an acoustic wave device for wide passband applications with an excellent temperature coefficient, small size, and a clean response.

### Description of the Related Technology

Acoustic wave devices, including surface acoustic wave (SAW) devices and temperature compensated surface acoustic wave (TC-SAW) devices, are frequently used in acoustic wave filters. Acoustic wave filters can filter radio frequency (RF) signals in radio frequency electronic systems. TC-SAWs are widely used for high performance RF communication modules.

FIGS. 1A and 1B show side and plan views of an exemplary conventional TC-SAW device 100. FIG. 1A is a cross-section through the line marked B in FIG. 1B, and FIG. 1B is a cross-section through the line marked A in FIG. 1A.

The conventional TC-SAW device 100 includes a piezoelectric substrate 102 and an interdigital transducer (IDT) 106 disposed on the piezoelectric substrate 102. A temperature compensation layer 104 is disposed over an upper surface of the IDT 106 and the piezoelectric substrate 102. A passivation layer 108 is disposed on an upper surface of the temperature compensation layer 104.

The IDT 106 shown in FIG. 1B includes a pair of interlocking comb shaped electrodes, each electrode including a bus bar 106a and a plurality of fingers 106b that extend from the bus bar 106a, typically perpendicularly, towards the bus bar 106a in the opposite electrode. The main surface acoustic wave generated by the IDT 106 travels perpendicular to the lengthwise direction of the IDT fingers 106b, and parallel to the lengthwise direction of the IDT bus bars 106a.

Moving towards 5G applications, wider passbands and handling of higher powers are both desired. Better temperature stability is also important, to prevent the filter from failing under a high power input due to thermal runaway. Downsizing is an additional important aspect of filter development.

Various methods have been explored to provide a high electromechanical coupling coefficient (k²) and an excellent temperature coefficient of frequency (TCF). For example, multilayer piezoelectric substrates (MPSs) are one way to provide excellent Q-factor, k² and TCF. However, MPSs are expensive and can lead to a size increase. Thicker temperature compensation layers in TC-SAW devices such as that in FIGS. 1A and 1B have also been used to provide a good TCF, however k² is very small in such devices and cannot cover the wider passbands desired today.

### SUMMARY

According to one embodiment there is provided an acoustic wave device. The acoustic wave device comprises a piezoelectric substrate, a temperature compensation layer disposed on the piezoelectric substrate, an interdigital transducer embedded within the temperature compensation layer and spatially separated from the piezoelectric substrate, the interdigital transducer being configured to generate a main acoustic wave in response to an electrical signal, and a passivation layer disposed on the temperature compensation layer.

In one example the separation between the interdigital transducer and the piezoelectric substrate is between about 0.002 λ and 0.01 λ, where λ is the wavelength of the main acoustic wave generated by the interdigital transducer during operation.

In one example the separation between the interdigital transducer and a top surface of the temperature compensation layer is between about 0.3 λ and 0.4 λ, where λ is the wavelength of the main acoustic wave generated by the interdigital transducer during operation.

In one example the interdigital transducer includes a pair of interdigital transducer electrodes, each electrode having a bus bar and a plurality of fingers extending from the bus bar towards the bus bar of the other electrode.

In one example the fingers of each interdigital transducer electrode interleave with one another in a first region of the interdigital transducer and form a gap region between the ends of the fingers of one of the electrodes and the bus bar of the other electrode.

In one example the first region includes a central portion and two edge portions, each edge portion extending from the tips of the plurality of fingers of one of the electrodes towards the center of the central portion.

In one example the acoustic wave device further comprises a suppression element configured to suppress a transverse mode of the interdigital transducer.

In one example the suppression element is a pair of mass loading strips embedded within the temperature compensation layer.

In one example the pair of mass loading strips each overlap a respective one of the edge portions of the first region of the interdigital transducer.

In one example the pair of mass loading strips each extend in a direction parallel to the bus bars of the interdigital transducer along the length of the interdigital transducer.

In one example the pair of mass loading strips each have a width in a direction parallel to the fingers of the interdigital transducer electrodes of between about 0.5 λ, and 1.5 λ, where λ is the wavelength of the main acoustic wave generated by the interdigital transducer during operation.

In one example the pair of mass loading strips each have a thickness of between about 0.005 λ and 0.04 λ, where λ is the wavelength of the main acoustic wave generated by the interdigital transducer during operation.

In one example the pair of mass loading strips are formed from a conductive material.

In one example the pair of mass loading strips are formed from a material with a higher density than a density of the temperature compensation layer.

In one example the suppression element is a pair of cut out portions in the passivation layer.

In one example the pair of cut out portions each overlap a respective one of the edge portions of the first region of the interdigital transducer.

In one example the pair of cut out portions each extend in a direction parallel to the bus bars of the interdigital transducer along the length of the interdigital transducer.

In one example the pair of cut out portions each have a width in a direction parallel to the fingers of the interdigital transducer electrodes of between about 0.5 λ, and 1.5 λ, where λ is the wavelength of the main acoustic wave generated by the interdigital transducer during operation.

In one example the pair of cut out portions extend in a direction parallel to the fingers of the interdigital transducer electrodes up to an outer edge of the acoustic wave device.

In one example the pair of cut out portions each have depth of between about 0.005 λ and 0.04 λ, where λ is the wavelength of the main acoustic wave generated by the interdigital transducer during operation.

In one example the thickness of the passivation layer is largest in the region overlapping the central portion of the first region of the interdigital transducer.

In one example the suppression element is formed from a pair of hammer portions in each of the plurality of fingers, each of the hammer portions being located in a respective one of the edge portions of the first region of the interdigital transducer, and each having a width larger than the width of each finger in the central portion of the first region of the interdigital transducer.

In one example a duty factor of the interdigital transducer electrodes in the edge portions of the first region is greater than the duty factor of the interdigital transducer electrodes in the central portion of the first region.

In one example each of the interdigital transducer electrodes includes a second bus bar that is located within the gap region.

In one example each of the second bus bars includes one or more gaps positioned along the length of the second bus bars.

In one example the layer of piezoelectric substrate is formed of lithium niobate.

In one example the piezoelectric substrate has a cut angle in a range from -15° to +25°.

In one example the temperature compensation layer includes one of silicon dioxide or doped silicon dioxide.

In one example the interdigital transducer includes a lower layer of material and an upper layer of material, the upper layer of material having a higher conductivity and lower density than the lower layer of material.

In one example the upper layer of material is formed from at least one of aluminum or copper, and the lower layer of material is formed from at least one of titanium, molybdenum, tungsten, gold, silver, platinum, ruthenium, or nickel.

In one example the passivation layer is formed of silicon nitride.

In one example a duty factor of the interdigital transducer electrodes in the edge portions of the first region is greater than the duty factor of the interdigital transducer electrodes in the central portion of the first region.

In one example the suppression element includes at least one of a mass loading strip embedded within the temperature compensation layer, a cut out portion in the passivation layer, or hammer portions in each of the plurality of fingers, the hammer portions having a width larger than the width of each finger away from the hammer portion.

According to another embodiment there is provided an acoustic wave device. The acoustic wave device comprises a piezoelectric substrate, a temperature compensation layer disposed on the piezoelectric substrate, and an interdigital transducer disposed within the temperature compensation layer and spatially separated from the piezoelectric substrate, the interdigital transducer being configured to generate an acoustic wave in response to an electrical signal.

In one example the acoustic wave device further comprises a suppression element configured to suppress a transverse mode of the interdigital transducer.

According to another embodiment there is provided a radio frequency filter comprising at least one acoustic wave device, the at least one acoustic wave device including a piezoelectric substrate, a temperature compensation layer disposed on the piezoelectric substrate, an interdigital transducer embedded within the temperature compensation layer and spatially separated from the piezoelectric substrate, the interdigital transducer being configured to generate an acoustic wave in response to an electrical signal, and a passivation layer disposed on the temperature compensation layer.

According to another embodiment there is provided an electronics module comprising at least one radio frequency filter that includes at least one acoustic wave device, the at least one acoustic wave device including a piezoelectric substrate, a temperature compensation layer disposed on the piezoelectric substrate, an interdigital transducer embedded within the temperature compensation layer and spatially separated from the piezoelectric substrate, the interdigital transducer being configured to generate an acoustic wave in response to an electrical signal, and a passivation layer disposed on the temperature compensation layer.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1A is a cross-sectional view of an exemplary conventional TC-SAW device;

FIG. 1B is a plan view of an exemplary conventional TC-SAW device;

FIG. 2A is a cross-sectional view of an acoustic wave device according to aspects disclosed herein;

FIG. 2B is a plan view of an acoustic wave device according to aspects disclosed herein;

FIG. 3A is a cross-sectional view of an acoustic wave device according to aspects disclosed herein;

FIG. 3B is a cross-sectional view of an acoustic wave device according to aspects disclosed herein;

FIG. 3C is a plan view of an acoustic wave device according to aspects disclosed herein;

FIG. 3D is a plan view of an acoustic wave device according to aspects disclosed herein;

FIG. 4A is a graph showing a comparison of admittance curves of an acoustic wave device according to aspects disclosed herein and an acoustic wave device without a floating IDT;

FIG. 4B is a graph showing a comparison of admittance curves of an acoustic wave device according to aspects disclosed herein with an acoustic wave device without a floating IDT;

FIG. 4C is a graph showing a comparison of quality factor curves of an acoustic wave device according to aspects disclosed herein with an acoustic wave device without a floating IDT;

FIG. 5A is a graph showing a comparison of admittance curves of an acoustic wave device according to aspects disclosed herein and exemplary devices without floating IDTs;

FIG. 5B is a graph showing a comparison of admittance curves of an acoustic wave device according to aspects disclosed herein and exemplary devices without floating IDTs;

FIG. 5C is a graph showing a comparison of quality factor curves of an acoustic wave device according to aspects disclosed herein and exemplary devices without floating IDTs;

FIG. 6A is a partial cross-section of an acoustic wave device showing a distance which is varied in a parametric sweep;

FIG. 6B is a graph showing the variation of the velocity of the main acoustic mode with the distance shown in FIG. 6A;

FIG. 6C is a graph showing the variation of TCF with the distance shown in FIG. 6A;

FIG. 6D is a graph showing the variation of k² with the distance shown in FIG. 6A;

FIG. 6E is a graph showing the variation of static capacitance with the distance shown in FIG. 6A;

FIG. 7A is a partial cross-section of an acoustic wave device showing distances which are varied in a parametric sweep;

FIG. 7B is a graph showing the variation of the velocity of the main acoustic mode with the distances shown in FIG. 7A;

FIG. 7C is a graph showing the variation of k² with the distances shown in FIG. 7A;

FIG. 7D is a graph showing the variation of TCFs with the distances shown in FIG. 7A;

FIG. 7E is a graph showing the variation of TCFp with the distances shown in FIG. 7A;

FIG. 8A is a partial cross-section of an acoustic wave device showing a distance which is varied in a parametric sweep;

FIG. 8B is a graph showing the variation of the velocity of the main acoustic mode with the distance shown in FIG. 8A;

FIG. 8C is a graph showing the variation of TCF with the distance shown in FIG. 8A;

FIG. 8D is a graph showing the variation of k² with the distance shown in FIG. 8A;

FIG. 8E is a graph showing the variation of static capacitance with the distance shown in FIG. 8A;

FIG. 9A is a graph showing a comparison of admittance curves of acoustic wave devices according to aspects disclosed herein;

FIG. 9B is a graph showing a comparison of admittance curves of acoustic wave devices according to aspects disclosed herein;

FIG. 9C is a graph showing a comparison of quality factor curves of acoustic wave devices according to aspects disclosed herein;

FIG. 10A is a graph showing a comparison of admittance curves of acoustic wave devices according to aspects disclosed herein;

FIG. 10B is a graph showing a comparison of admittance curves of acoustic wave devices according to aspects disclosed herein;

FIG. 11A is a graph showing a comparison of admittance curves of acoustic wave devices according to aspects disclosed herein;

FIG. 11B is a graph showing a comparison of admittance curves of acoustic wave devices according to aspects disclosed herein;

FIG. 11C is a graph showing a comparison of quality factor curves of acoustic wave devices according to aspects disclosed herein;

FIG. 12 shows an example of a ladder filter in which multiple acoustic wave devices according to aspects disclosed herein may be combined;

FIG. 13 is a block diagram of one example of a filter module that can include one or more acoustic wave devices according to aspects of the present disclosure;

FIG. 14 is a block diagram of one example of a front-end module that can include one or more filter modules including acoustic wave devices according to aspects of the present disclosure; and

FIG. 15 is a block diagram of one example of a wireless device including the front-end module of FIG. 14.

### DETAILED DESCRIPTION

Aspects and embodiments described herein are directed to an acoustic wave device, a radio frequency filter and an electronics module. The acoustic wave device comprises a piezoelectric substrate, a temperature compensation layer disposed on the piezoelectric substrate, and an interdigital transducer embedded within the temperature compensation layer and spatially separated from the piezoelectric substrate. The interdigital transducer is configured to generate an acoustic wave in response to an electrical signal. A passivation layer is disposed on the temperature compensation layer. The acoustic wave device can be used in wide passband applications, and has an excellent temperature coefficient, small size, and a clean response.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, or all of the described terms.

Aspects are described below through embodiments of the acoustic wave device, in particular, temperature compensated surface acoustic wave (TC-SAW) devices. However, as would be understood by the skilled person, various different excitation modes are possible in acoustic wave resonators, filters and devices. As well as surface acoustic waves other types of acoustic wave are possible such as boundary acoustic waves and guided acoustic waves. References to surface acoustic waves and TC-SAW resonators/devices in the following description are not intended to limit the disclosure from including or covering other possible types of acoustic wave excitation.

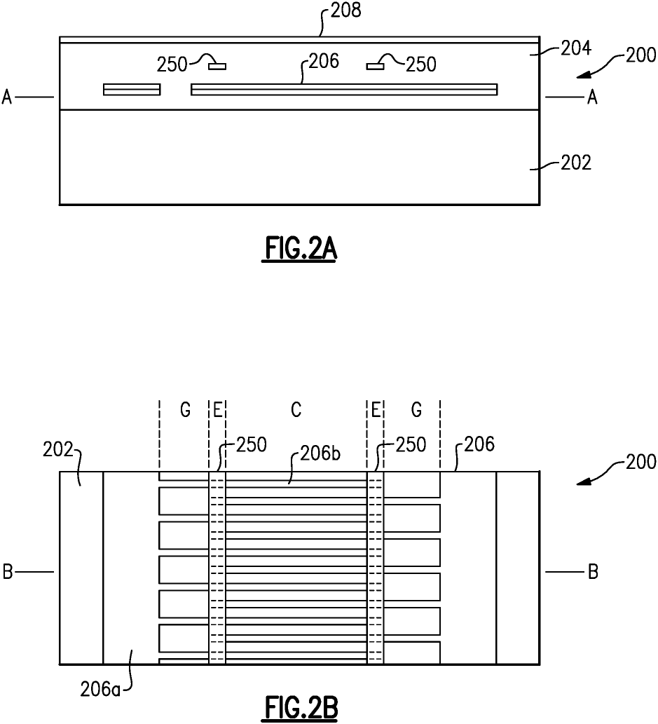

FIGS. 2A and 2B shown a side view and a plan view respectively of an acoustic wave device in one embodiment. FIG. 2A is a cross-section through the line marked B in FIG. 2B, and FIG. 2B is a cross-section through the line marked A in FIG. 2A.

The acoustic wave device 200 of FIGS. 2A and 2B is a TC-SAW device. The acoustic wave device 200 includes a piezoelectric substrate 202 and a temperature compensation layer 204 that is disposed on an upper surface of the piezoelectric substrate 202. An interdigital transducer (IDT) 206 is embedded within the temperature compensation layer 204 and is spatially separated from the piezoelectric substrate 202. The IDT 206 is floating in the temperature compensation layer 204. A passivation layer 208 is disposed on an upper surface of the temperature compensation layer 204.

In the piezoelectric substrate 202, lithium niobate (LiNbO₃, also abbreviated as “LN” herein) may be used as the piezoelectric material. In a particular embodiment, low cut YX-LN (low cut rotated Y cut X propagation LN) could be used. Low cut here means that the cut angle is between -15° and +25°. The LN piezoelectric substrate 202 is defined by Euler angles ( ø, θ , ɸ ) within the ranges of 75< θ <115, -15< ɸ <15, -15< ɸ <15. Use of low cut lithium niobate results in a very large k².

The temperature compensation layer 204 can include any suitable temperature compensation material or dielectric material. For example, the temperature compensation layer 204 can be a silicon dioxide (SiO₂) layer. Other examples may include doped materials such as F doped SiO₂, or Ti doped SiO₂.The temperature compensation layer 204 can be a layer of any other suitable material having a positive temperature coefficient of frequency for acoustic wave devices with a piezoelectric layer having a negative coefficient of frequency. For instance, the temperature compensation layer 14 can be a silicon oxyfluoride (SiOF) layer in certain applications. A temperature compensation layer 14 can include any suitable combination of SiO₂ and/or SiOF. The temperature compensation layer reduces the change in frequency response of the acoustic wave device with changes in temperature.

The IDT 206 includes a pair of interlocking comb shaped electrodes, each electrode including a bus bar 206a, a plurality of fingers 206b that extend from the bus bar 206a, typically perpendicularly, towards the bus bar 206a in the opposite electrode. The IDT 206 is configured to generate a main surface acoustic wave having a wavelength λ in response to an input electrical signal. The main surface acoustic wave generated by the IDT 206 travels perpendicular to the lengthwise direction of the IDT fingers 206b, and parallel to the lengthwise direction of the IDT bus bars 206a. Typically the distance between the central points of each adjacent finger 206b extending from the same bus bar 206a is equal to the wavelength λ of the surface acoustic wave generated. The bus bars 206a of each of the pair or IDT electrodes are parallel and opposing each other, and the plurality of fingers 206b of each IDT electrode extend towards to the bus bar 206a of the opposing electrode, such that the fingers 206b interlock, typically with a distance of λ/2 between the center of each adjacent finger 206b extending from opposite bus bars 206a.

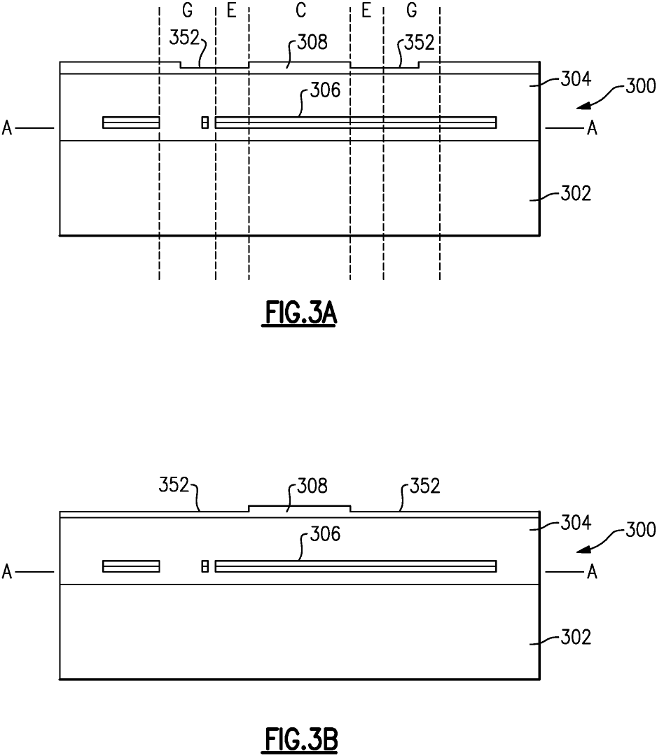

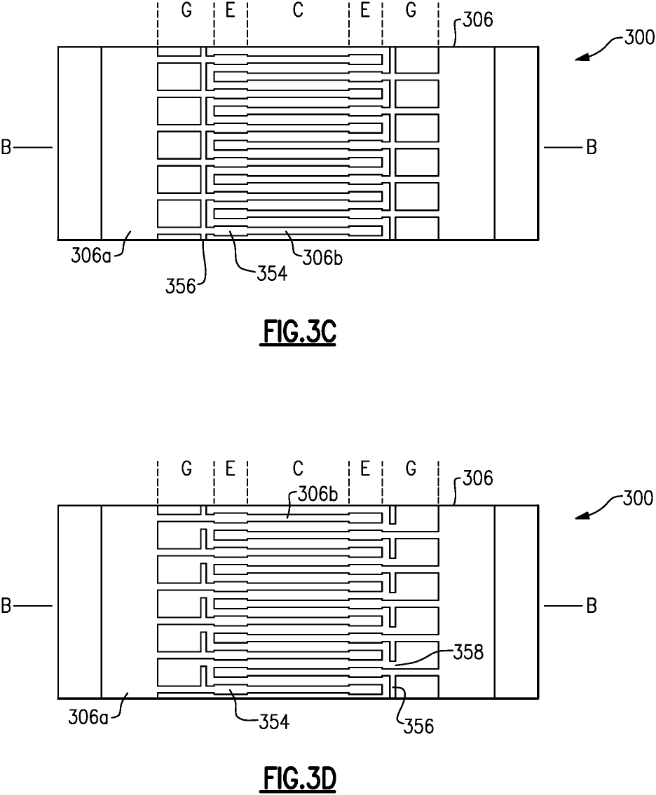

Alternative and more complex IDT configurations may be used, for example double interdigitated electrode IDTs, IDTs including dummy electrodes or the like. In general any type of IDT may be used, as would be understood by the skilled person. Further specific IDT configurations will be discussed below in FIGS. 3C and 3D.

As illustrated in FIG. 2A, the IDT electrodes may be layered electrodes including an upper layer of a highly conductive but low-density material, for example, aluminum (Al) or copper (Cu), or an aluminum-copper alloy, and a lower layer of a less conductive, but more dense material, for example, titanium (Ti), molybdenum (Mo), tungsten (W), gold (Au), silver (Ag), platinum (Pt), ruthenium (Ru), or nickel (Ni). The denser lower layer may reduce the acoustic velocity of acoustic waves travelling through the device which may allow the IDT electrode fingers to be spaced more closely for a given operating frequency and allow the acoustic wave device to be reduced in size as compared to a similar device utilizing less dense IDT electrodes. The less dense upper layer may have a higher conductivity than the lower layer to provide the electrodes with lower overall resistivity than if they were formed entirely of the denser material. In a particular embodiment, the lower layer of the IDT may have a thickness of between about 0.01 λ and 0.08 λ, and the upper layer of the IDT may have a thickness of between about 0.02 λ and 0.08 λ, where λ is the wavelength of the main acoustic wave generated by IDT during operation. In some embodiments, single layer electrodes may also be used.

Regardless of the type of IDT used, the IDT 206 has a first region defined as the region that the fingers 206b of each interdigital transducer electrode interleave with one another. The surface acoustic wave is generated in the first region of the IDT. The first region of the IDT includes a central portion and two edge portions. The central portion is labeled by the letter C in FIG. 2B and the edge portions are labeled by the letter E. Each edge portion extends from the tips of the plurality of fingers of one of the electrodes towards the center of the central portion. The edge portions E include end portions of the IDT electrode fingers, and the central portion C is sandwiched between the edge portions. The purpose of the edge portions will be discussed in more detail below. The IDT also includes gap regions labeled by the letter G in FIG. 2B. The gap regions are located between the ends of the fingers 206b of one of the electrodes and the bus bar 206a of the other electrode. The dashed lines in FIG. 2B show the boundaries between the above described regions.

As mentioned above, the IDT 206 is located within the temperature compensation layer 204. The IDT 206 is surrounded on all sides by the temperature compensation layer 204 material, in this embodiment, SiO₂. This means the IDT 206 is not in contact with the piezoelectric substrate 202 and is therefore spatially separated from the piezoelectric substrate 202.

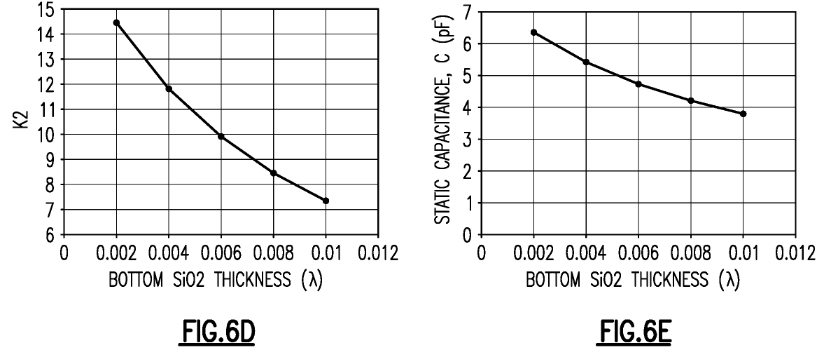

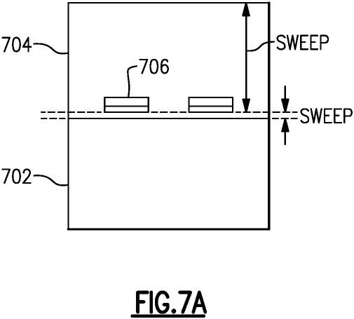

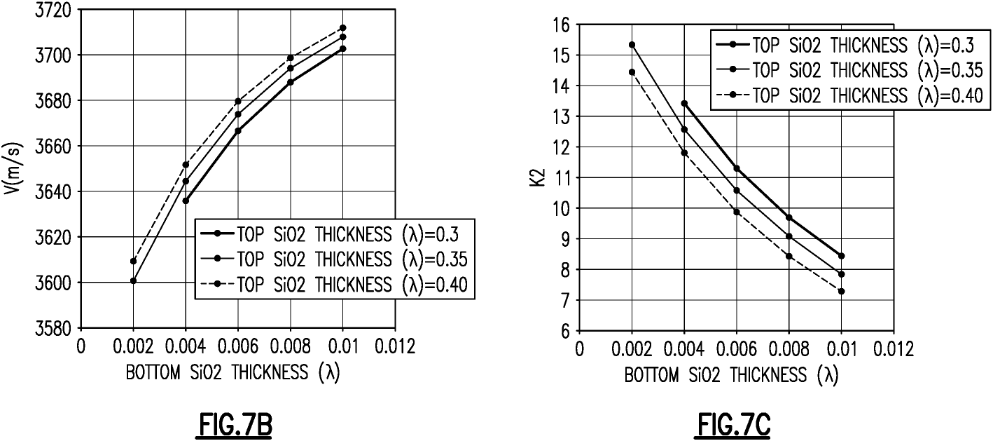

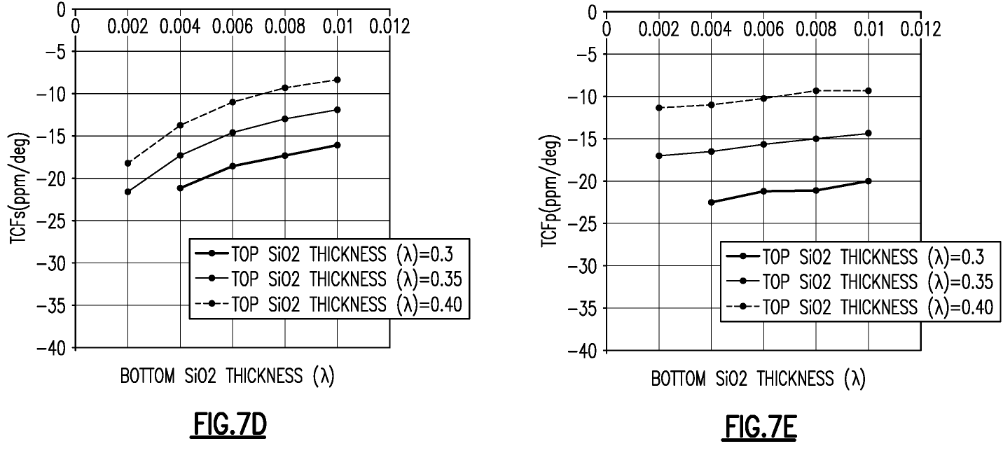

In a particular embodiment, the separation between the IDT 206 and the piezoelectric substrate 202 is between about 0.002 λ and 0.01 λ, where λ is the wavelength of the main acoustic wave generated by IDT during operation. The separation between the IDT 206 and the top surface of the temperature compensation layer 204 (onto which the passivation layer 208 is disposed) may be between about 0.3 λ and 0.4 λ, where λ is the wavelength of the main acoustic wave generated by the IDT during operation. The effect of the variation of these distances will be discussed in more detail in relation to FIGS. 6A to 7E below.

Suspending the IDT 206 within the temperature compensation layer 204, separated from the piezoelectric substrate 202, improves the TCF of the acoustic wave device. The advantages will be discussed in more detail in relation to FIGS. 6A to 6E below.

The passivation layer 208 may be disposed entirely over the upper surface of the temperature compensation layer 204. The passivation layer 208 performs frequency truncation and passivation. The passivation layer may be formed of silicon nitride (Si₃N₄, also abbreviated as “SiN” herein). In some embodiments, the passivation layer may be omitted without preventing correct function of the acoustic wave device. However, the passivation layer 208 is typically included on the upper surface of the temperature compensation layer 204, to avoid changes in characteristics due to external influences, such as humidity or other materials present during device fabricating processes.

The acoustic wave device 200 may also include a suppression element configured to suppress a transverse mode of the interdigital transducer. The presence of the transverse modes can hinder the accuracy and/or stability of acoustic wave devices, as well as hurt the performance of acoustic wave filters by creating relatively severe passband ripples and possibly limiting the rejection. Various alternative versions of the suppression element are possible, including mass loading strips, cut out portions in the passivation layer, and hammer portions in the fingers of the IDT. Each of these will be discussed in more detail below.

To reduce transverse mode excitation, the suppression element is used to create a border region with a different frequency from an active region of the IDT, according to the mode dispersion characteristic. This can be referred to as a “piston mode.” A piston mode can be obtained to cancel out the transverse wave vector in a lateral direction without significantly degrading k² or the Q-factor. By including a relatively small border region with a slower velocity on the edge of the acoustic aperture of a SAW or TC-SAW device, a propagating mode can have a zero (or approximately zero) transverse wave vector in the active aperture.

In the present embodiment shown in FIGS. 2A and 2B, the suppression element is a pair of mass loading strips 250 embedded within the temperature compensation layer 204, away from both the upper and lower surfaces of the temperature compensation layer 204. The mass loading strips 250 are suspended above the IDT 206 within the temperature compensation layer 204. The pair of mass loading strips 250 each extend in a direction parallel to the bus bars of the IDT and along the length of the IDT. The mass loading strips 250 each extend in the direction of propagation of the main surface acoustic wave generated by the IDT 206. The mass loading strips each overlap a respective one of the edge portions E of the first region of the IDT 206. The mass loading strips therefore bound the central portion C of the IDT 206. In FIG. 2B the position of the fingers 206b of the IDT are shown underneath the mass loading strips 250 using dotted lines.

In one example, the mass loading strips 250 can be conductive strips, for example strips of metal. In another example, the mass loading strips 250 are formed from a material with higher density than the density of the temperature compensation layer 204, for example, a heavy strip of dielectric material. The high-density/conductive mass loading strips decrease the acoustic velocity in the edge portions E relative to the acoustic velocity in the central portion C which aids in confining the acoustic waves generated during operation of the device within the central portion. The mass loading strips 250 can implement piston mode.

In one implementation, the mass loading strips 250 can be multi-layer conductive strip. The mass loading strips 250 may have a similar configuration as the multi-layered IDT described above. Namely, the mass loading strips 250 may include an upper layer of a highly conductive but low-density material, for example, aluminum (Al) or copper (Cu), or an aluminum-copper alloy, and a lower layer of a less conductive, but more dense material, for example, titanium (Ti), molybdenum (Mo), tungsten (W), gold (Au), silver (Ag), platinum (Pt), ruthenium (Ru), or nickel (Ni).

In one particular embodiment, the mass loading strips 250 each have a width (in a direction parallel to the lengthwise direction of the fingers 206b of the IDT electrodes) of between about 0.5 λ, and 1.5 λ, where λ is the wavelength of the main acoustic wave generated by the IDT 206 during operation. In one particular embodiment, the mass loading strips may each have a thickness of between about 0.005 λ and 0.04 λ. In general, the denser the material used in the mass loading strips 250, the thinner the mass loading strips 250 can be made.

As described above, the mass loading strips 250 overlap the edge portions E of the IDT 206, when seen from a plan view. The mass loading strips may be positioned directly above the edge portions E, with one edge of the mass loading strips 250 in line with the terminus of each of the fingers 206b of the IDT, and the other edge of the mass loading strips 250 located closer to the center of the central portion C. However, a slight offset in the location of the mass loading strips in the direction parallel to the lengthwise directions of the IDT fingers 206a may be acceptable in some embodiments. For example, the mass loading strips 250 may be shifted by up to 0.3 λ in either direction. In particular, the mass loading strips 250 may be moved inwards towards the central portion to set the waveform of the IDT 206.

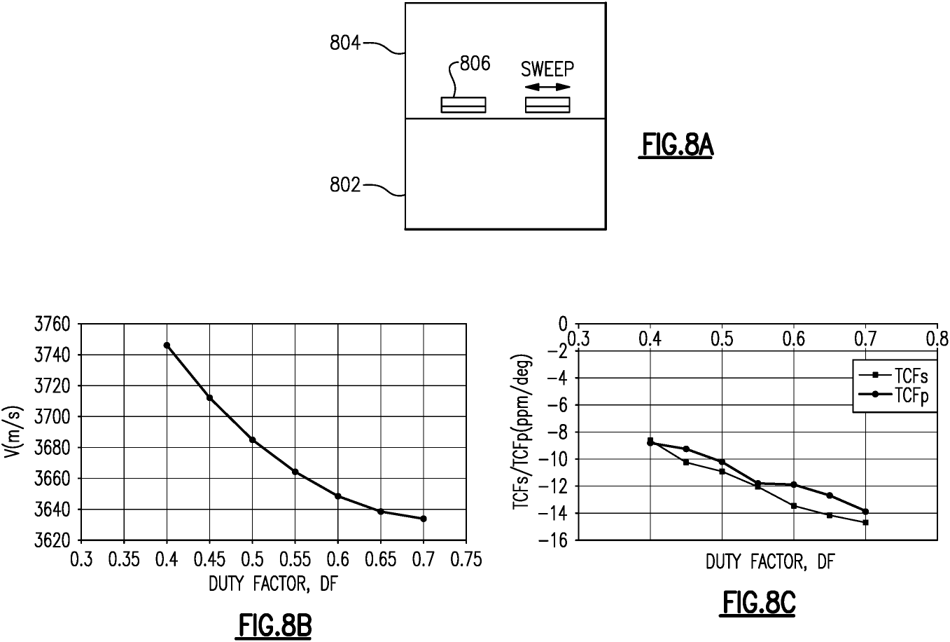

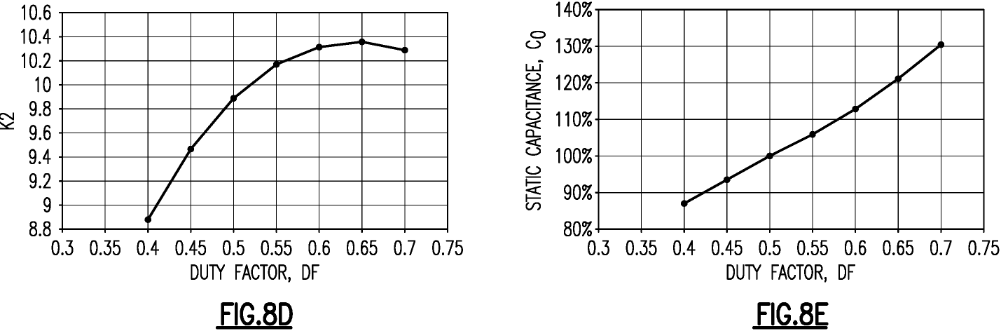

The acoustic wave device 200 of FIGS. 2A to 2B provides a device with an excellent TCF due to the floating IDT, a clean response with suppressed transverse modes due to the mass loading strips, and a large k² due to the low cut piezoelectric substrate. Use of the mass loading strips 250 also allows a duty factor of the IDT that is greater than or equal to 0.5 to be used, as will be discussed below along with further advantages in relation to the graphs of FIGS. 8A to 10B.

First, an alternative embodiment of the TC-SAW device will be described in relation to FIG. 3A. The acoustic wave device 300 of FIG. 3A includes a piezoelectric substrate 302, a temperature compensation layer 304 disposed on an upper surface of the piezoelectric substrate 302, an IDT 306 embedded within the temperature compensation layer 304 and spatially separated from the piezoelectric substrate 302, and a passivation layer 308 disposed on an upper surface of the temperature compensation layer 304. The description for each of the corresponding features of FIGS. 2A and 2B is also applicable to the features of the acoustic wave device 300 here and will therefore not be repeated.

The embodiment of FIG. 3A differs from that of FIGS. 2A and 2B in that no mass loading strips are present. Instead, the suppression element is a pair of cut out portions 352 in the passivation layer. The pair of cut out portions 352 each extend in a direction parallel to the bus bars 306a of the IDT 306 along the length of the IDT in the direction of propagation of the main surface acoustic wave generated by the IDT 306. In the present embodiment, the passivation layer is formed of silicon nitride (SiN), therefore the cut out portions 352 can be described as SiN trenches.

Similarly to the mass loading strips 250 of the previous embodiment, the cut out portions 352 each overlap a respective one of the edge portions E of the first region of the IDT 306 (when seen from a plan view). The cut out portions 352 therefore bound the central portion C of the IDT 306 to implement a piston mode, and thus suppress the transverse modes. The cut out portions 352 implement the piston mode by reducing the magnitude of the velocity in the underlying region of the acoustic wave device, similarly to the mass loading strips 250 in the previous embodiment. The passivation layer 308, in conjunction with the cut out portions 352, helps to contain acoustic energy within the acoustic wave device 300 due to the discontinuity in acoustic velocity between the central portion C of the IDT and the edge portion E of the IDT.

In one particular embodiment, the cut out portions 352 each have a width (in a direction parallel to the fingers 306b of the IDT electrodes) of between about 0.5 λ and 1.5 λ, where λ is the wavelength of the main acoustic wave generated by the IDT 306 during operation. In one particular embodiment, the cut out portions 352 may each have a depth of between about 0.005 λ and 0.04 λ. Similar to the mass loading strips, the cut out portions 352 may be offset from the edge portions E in the direction parallel to the IDT fingers 306a by about ±0.3λ. The depths of the cut out portions affects the acoustic wave velocity in the regions below the cut out portions (the edge portions E). The depths are chosen to set the difference in acoustic wave velocity between the central portion C of the IDT and the edge portions E of the IDT to implement the piston mode.

In a particular embodiment, the thickness of the passivation layer 308 away from the cut out portions 352 is between about 30 nm and 210 nm, and the depths of the cut out portions may be between about 20 nm and 160 nm. The depths of the cut out portions may be less than the thickness in the cut out portions, such that the thickness of the passivation layer 308 remaining in the cut out portions is between about 10 nm and 50 nm.

In some embodiments, the width of the pair of cut out portions 352 may extend in a direction parallel to the fingers of the IDT electrodes up to an outer edge of the acoustic wave device 300, as is shown in FIG. 3B. The cut out portions 352 extend over the entire acoustic wave device except for the central portion C of the IDT 306. This results in an acoustic wave device where the thickness of the passivation layer 308 is largest in the region overlapping the central portion C of the first region of the IDT 306. This can result in less material being used in the passivation layer, as well as a reduction in size of the acoustic wave device.

The cut out portions 352 of either of FIGS. 3A or 3B could be used instead of the mass loading strips 250 of the previous embodiment, or in combination with the mass loading strips 250 of the previous embodiment. Either of or both of the cut out portions 352 and the mass loading strips 250 could be used with the IDT of the type shown in FIG. 2B.

Additionally or alternatively, an IDT of the type shown in FIG. 3C, which includes a hammer head structure to suppress a transverse mode of the interdigital transducer, may be used. The hammer head type IDT 306, includes a pair of interlocking electrodes, each electrode including a bus bar 306a, a plurality of fingers 306b that extend from the bus bar 306a towards the bus bar 306a in the opposite electrode. The IDT 306 shares the same features as the IDT 206 of FIG. 2B, and a description thereof will not be repeated here. The hammer head type IDT 306 further includes hammer portions 354 in each of the plurality of fingers 306b. The hammer portions 354 are located in the edge portions E of the first region of the IDT 306. Each IDT finger 306b includes a pair of hammer portions 354, one located in the edge portion E at the end of that IDT finger, and the other located in the edge portion E corresponding to the end of the IDT fingers of an adjacent IDT electrode. The hammer portions 354 have a width in a direction parallel to the lengthwise direction of the bus bars larger than the width of each finger in the central portion C of the first region of the IDT 306. A duty factor of the IDT 306 in the edge portions E is greater than the duty factor of the IDT in the central portion C.

In some embodiments, the hammer portions in the IDT may have a thickness larger than the thickness of each finger in the central portion C of the first region of the IDT, instead of or as well as having a larger width in the hammer portions. An increase in width or an increase in thickness of the IDT in the edge portions E both reduce the acoustic velocity in those regions, and therefore can implement a piston mode.

Each electrode of the hammer head type IDT 306 may include a second bus bar 356 that is located within the gap region G. The second bus bars 356 extend parallel to the bus bars 306a and are located adjacent to the edge portions E of the first region of the IDT 306. The second bus bars 356 are thinner than the bus bars 306a, and may be referred to as “mini bus bars”. The second bus bars 356 work in conjunction with the hammer portions 354 to suppress the transverse modes more effectively.

In some embodiments, the second bus bars 356 each include one or more gaps 358 (or discontinuities) positioned along the length of the second bus bars 356. This configuration is shown in FIG. 3D. The gaps 358 may be spaced periodically along the second bus bar 356, adjacent to the cross over point between the second bus bars 356 and each of the fingers 306a of the IDT electrodes. The remaining sections of the second bus bars 356 extend from a respective one of each of the fingers 306b into the gap portion G. The remaining sections of the second bus bars 356 may extend a distance so as to overlap with the width of the hammer portion 354 on the adjacent finger 306b of the other IDT electrode. These remaining sections may be referred to as “gap hammers”. In some embodiments the distance between the tips of one set of IDT fingers 306b and the gap hammers may be smaller than the distance between the gap hammers and the proximate bus bar 306a. The distance between the tips of one set of IDT fingers 306b and the gap hammers may also be smaller than the width of the IDT fingers 306b in the edge portions E and/or central portion C. Including the gaps 358 in the second bus bars 356 can improve the performance of the transverse mode suppression.

The hammer head type IDT 306 shown in either of FIGS. 3C or 3D could be used instead of the cut out portions 352 and/or the mass loading strips 250 of the previous embodiments. The hammer portions 354 would act as the suppression means, suppressing the transverse modes of the IDT. In other embodiments, the hammer head type IDT 306 could be used in combination with one or both of the cut out portions 352 and the mass loading strips 250 of the previous embodiments.

The shape and size of the hammer portions 354 and the shape and size of the second bus bars 356/gap hammers cause the acoustic wave device to exhibit an acoustic velocity in the gap regions G that is greater than an acoustic velocity in the central portion C that is, in turn, greater than an acoustic velocity in the edge portions E. This suppresses the transverse modes and obtains the piston mode distribution.

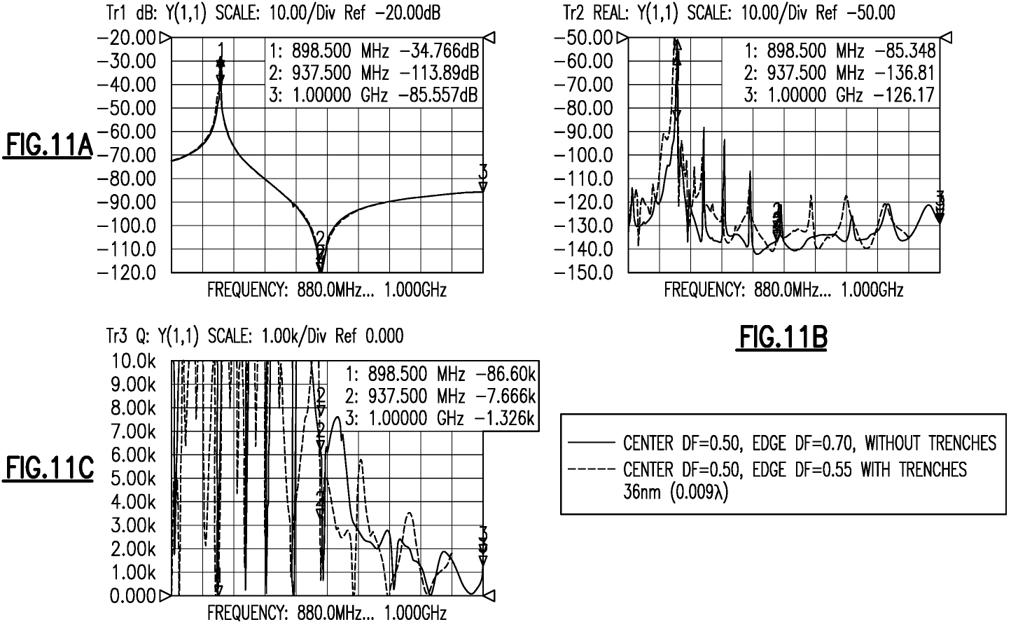

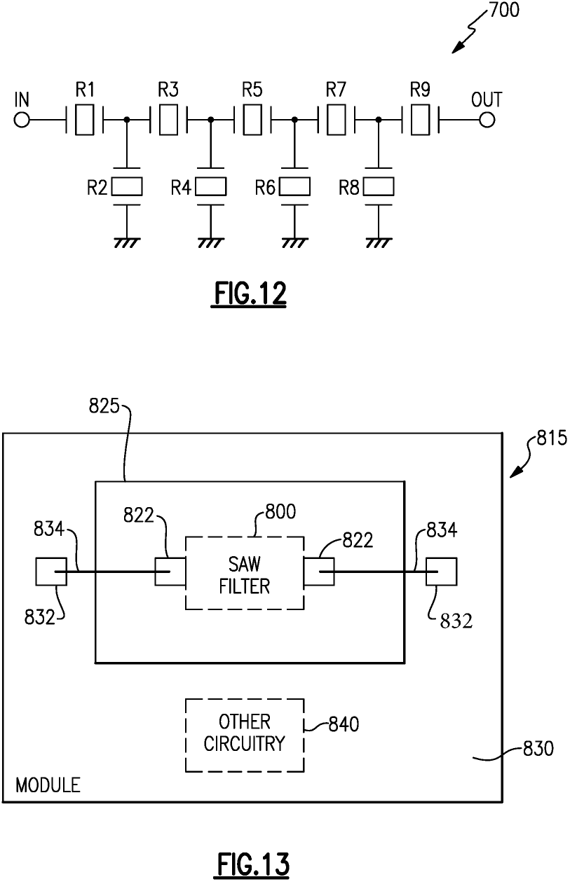

The different embodiments of the acoustic wave device described in FIGS. 3A to 3D each provide a device with an excellent TCF due to the floating IDT, a clean response with suppressed transverse modes due to the suppression element (the cut out portions 352 and/or hammer portions 354 of the hammer head type IDT), and a large k² due to the low cut piezoelectric substrate. Use of the cut out portions 352 and hammer head type IDT in combination can have further advantages, particularly for the duty factor of the IDT, as will be discussed in relation to FIGS. 11A to 11C below.

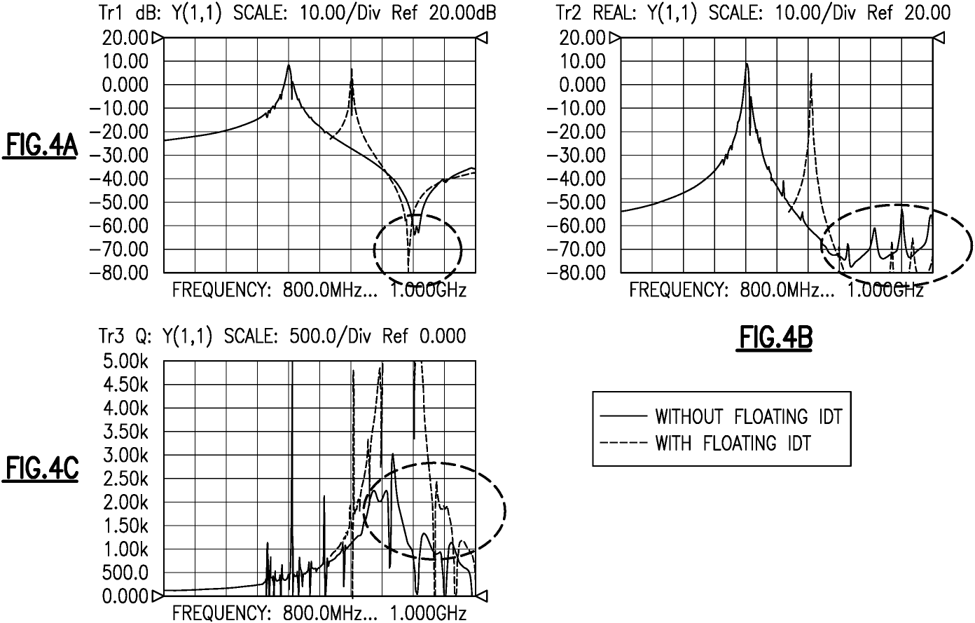

Summarizing the above described embodiments, in the embodiments disclosed herein the IDT is suspended within the temperature compensation layer. It is desirable to suppress transverse modes, and so a suppression element may be included that includes at least one of (or a combination of) a mass loading strip embedded within the temperature compensation layer, a cut out portion in the passivation layer, or a hammer portion in each of the plurality of fingers in the IDT, the hammer portion having a width larger than the width of each finger away from the hammer portion. The specific advantages of various embodiments will now be discussed in relation to the graphs of FIGS. 4A to 11C below.

FIGS. 4A to 4C are simulation graphs showing a comparison between admittance curves (complex FIG. 4A, and real FIG. 4B) and quality factor curves (Q-factor, FIG. 4C) of an acoustic wave device with a floating IDT and a comparative example without a floating IDT. The simulation of FIG. 4C is based on no mechanical loss and a series resistive loss of 0.2 Ω, as well as an IDT with a duty factor of 0.4 in the central portion C and 0.49 in the edge portions E.

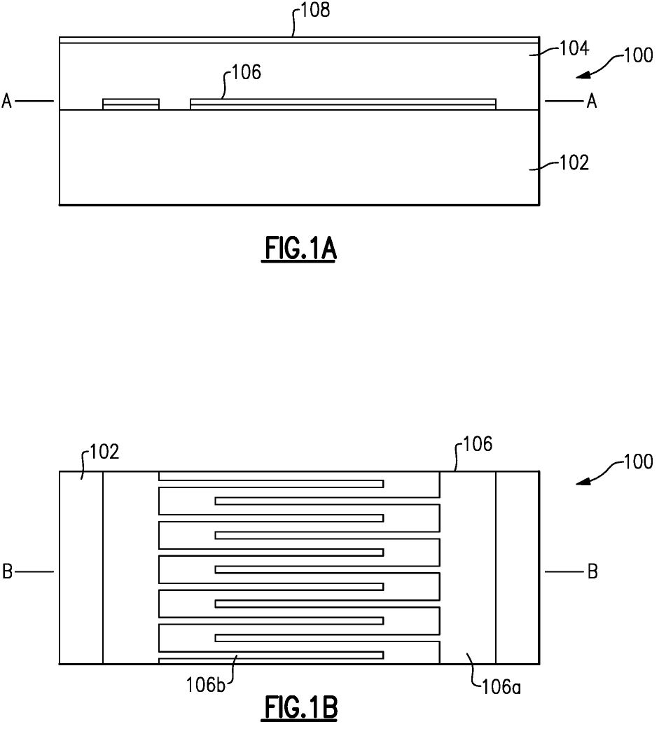

For the simulations in FIGS. 4A to 4C, an acoustic wave device with a hammer head type IDT (such as that shown in FIG. 3C) is used as the suppression means to reduce the transverse modes. No mass loading strips are used and no cut out portions in the passivation layer are used. In the graphs of FIGS. 4A to 4C, the solid lines are for an exemplary device with the IDT disposed on the upper surface of the piezoelectric substrate (such as shown in FIG. 1A), whereas the dashed lines are for an acoustic wave device with a floating IDT spatially separated from the piezoelectric substrate.

As can be seen highlighted by the dashed circles in FIGS. 4A to 4C, by separating the IDT from the piezoelectric substrate (for example, by including a layer of SiO₂ underneath the IDT) the Q-factor is improved and side leakage (energy moving in direction parallel to lengthwise directions of the IDT fingers) and transverse modes are reduced. As discussed above, a large k² can be achieved using low cut YX-LN, however this makes the Q-factor worse near anti resonance. By suspending/floating the IDT in the temperature compensation layer the Q-factor near anti resonance (Qp) is improved (best seen in FIG. 4A). As shown in FIG. 4C, the theoretical Qp limit is over 5000 when the IDT is floating, whereas Qp is considerably smaller when the IDT is disposed against the piezoelectric substrate, due to leakage. As shown in FIG. 4B, leakage starts before the bulk wave cut off (1006 MHz, 4024 m/s), and also below the anti-resonant frequency fp, when the IDT is disposed against the piezoelectric substrate. When the IDT is made to float in the temperature compensation layer, energy is kept in the active region of the IDT and leakage is reduced.

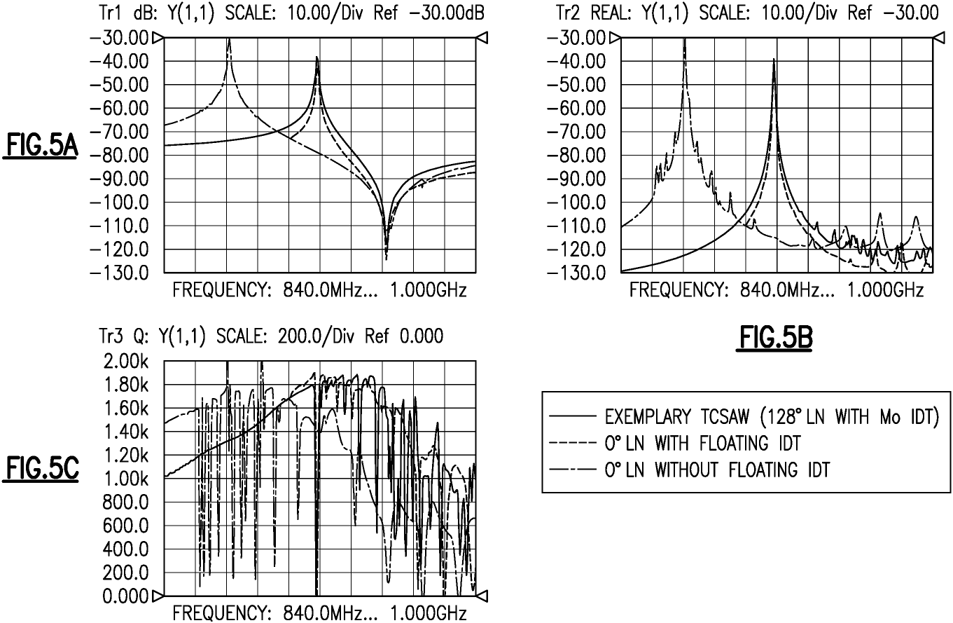

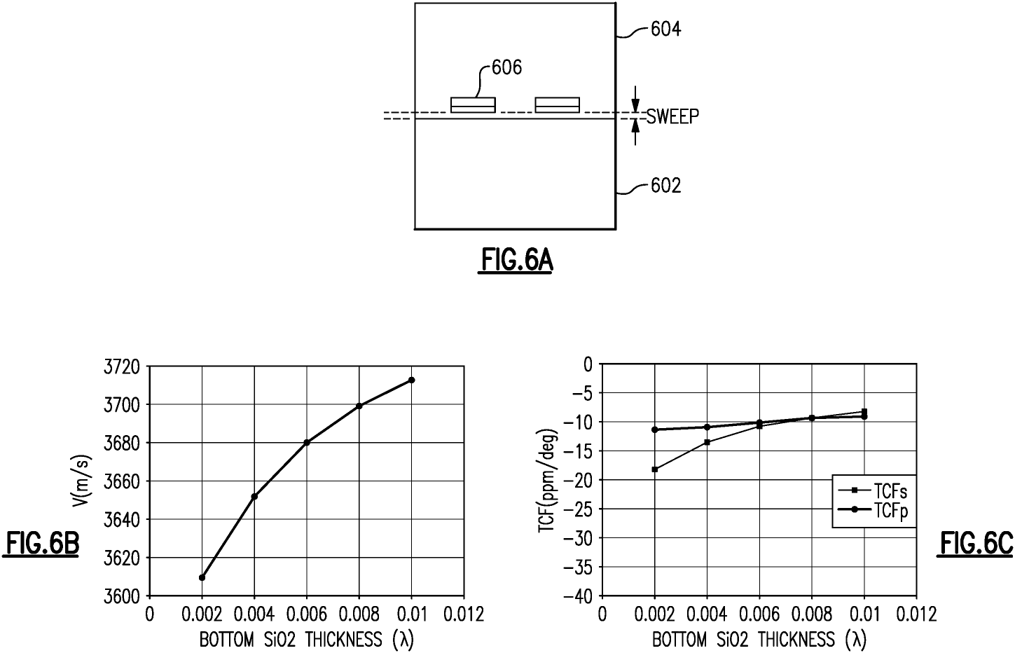

FIGS. 5A to 5C are simulation graphs that are the same as FIGS. 4A to 4C, except that an isotropic loss of 0.0006 has been included in all materials in the simulation, so that a more realistic value for Q-factor is given. In addition, FIGS. 5A to 5C also include a third curve on each of the graphs (the solid curve in FIGS. 5A to 5C) which shows the characteristics of an exemplary TC-SAW device available on the market. The exemplary TC-SAW has a piezoelectric substrate made of lithium niobate (LN) with a 128° cut angle, and an IDT disposed against the piezoelectric substrate and made of molybdenum (Mo). As can be seen from the graphs of FIGS. 5A to 5C, the acoustic wave device of with LN with a 0° cut angle and a floating IDT (the dashed curve in FIGS. 5A to 5C) has a similar Q-factor as the current exemplary 128° TC-SAW. However, the acoustic wave device with LN with a 0° cut angle and a floating IDT has a larger k² and a better TCF than the exemplary TC-SAW device.

FIGS. 6A to 6E show how various parameters vary as the distance between the IDT and the piezoelectric substrate is varied. Specifically FIG. 6A is a partial cross-section of an acoustic wave device showing the distance (spatial separation) between the piezoelectric substrate 602 and the IDT 606, which is varied in the parametric sweep. The IDT 606 is floating in the temperature compensation layer 604. Here the temperature compensation layer is made of SiO₂, and hence the distance between the IDT 606 and the piezoelectric substrate 602 will be referred to herein as the “bottom SiO₂ thickness”. However, as would be understood the aspects and embodiments disclosed herein are not limited to SiO₂ in the temperature compensation layer.

FIGS. 6B to 6E show how each of the velocity of the main acoustic mode, TCF, k², and static capacitance respectively vary with the bottom SiO₂ thickness. Other fixed parameters used in the simulation are a duty factor of 0.5 in the IDT, a thickness of the bottom layer in the IDT made of platinum of 0.025 λ, a thickness of the upper layer in the IDT made of aluminum of 0.04 λ, and a thickness of SiO₂ above the IDT (the distance between the IDT and the passivation layer, referred to herein as the “top SiO₂ thickness”) equal to 0.4 λ, where λ is the wavelength of the main acoustic wave generated by the interdigital transducer during operation.

As can be seen from FIG. 6B, as the bottom SiO₂ thickness increases (as the IDT is moved further away from the piezoelectric substrate) the phase velocity of the main acoustic mode, and therefore the series resonance frequency fs, increases rapidly. FIG. 6C shows how the series TCF (TCFs) increases rapidly as the bottom SiO₂ thickness increases. TCFs is therefore significantly improved as the thickness of the bottom SiO₂ increases, with the magnitude of TCFs nearly halved over the bottom SiO₂ thickness range shown in FIG. 6C. A bottom SiO₂ thickness of 0.006 λ to 0.008 λ gives roughly identical series TCF (TCFs) and parallel TCF (TCFp), which is good for device performance.

As shown in FIG. 6D, k² decreases as bottom SiO₂ thickness increases. A larger k² is desirable, however the decrease in k² is compensated for by the very large k² produced by the low cut LN piezoelectric substrate. A k² equal to 7.4 (corresponding to 0.01 λ bottom SiO₂ thickness in FIG. 6D) is typically the lower limit for filter applications. Therefore, a bottom SiO₂ thickness of greater than 0 and less than 0.01 λ is acceptable based on k² in FIG. 6D, while still gaining the benefits of improved TCF and Q-factor, as well as some reduction in side leakage due to the floating IDT. FIG. 6E shows how the static capacitance also decreases as bottom SiO₂ thickness increases, which will be discussed in more detail below, after a discussion of FIGS. 7A to 7E.

FIGS. 7A to 7E are similar to FIGS. 6A to 6E, except that both the bottom SiO₂ thickness and the top SiO₂ thickness are varied in a parametric sweep, as shown in FIG. 7A. As previously, bottom SiO₂ thickness refers to the distance between the IDT 706 and the piezoelectric substrate 702, and top SiO₂ thickness refers to the distance between the IDT 706 and the top of the temperature compensation layer 704 (where the passivation layer is located). However, embodiments are not limited to use of SiO₂ in the temperature compensation layer.

FIGS. 7B to 7E show how each of the velocity of the main acoustic mode, k², TCFs and TCFp vary with the top and bottom SiO₂ thickness. The fixed parameters used for the IDT in the simulation are the same as those used in FIGS. 6B to 6E. A bottom SiO₂ thickness range of 0.002 λ to 0.01 λ has been used, and top SiO₂ thicknesses of 0.3 λ, 0.35 λ and 0.4 λ have been used. Advantageously, as can be seen from FIGS. 7B to 7E, a very wide tunability of the device characteristics, particularly TCF and k², is possible by varying the specific combination of top SiO₂ thickness and bottom SiO₂ thickness used.

Returning to FIG. 6E, the static capacitance decreases as bottom SiO₂ thickness increases. Although increasing the bottom SiO₂ thickness helps enhance the Q-factor and TCF, the accompanying decrease in static capacitance is undesirable. A decrease in static capacitance leads to increased size of the acoustic wave device for a given impedance, as static capacitance sets the limit on the IDT size. The increase in size can be tolerated, given the other benefits of the floating IDT. However, techniques to further reduce transverse modes without an additional reduction in static capacitance will now discussed.

FIGS. 8A to 8E are parametric sweep graphs similar to FIGS. 6A to 7E, however in FIGS. 8A to 8E the duty factor (DF) of the IDT is the parameter that is varied. The width of the IDT fingers compared to the width of the spacing between the IDT fingers sets the duty factor. Specifically, the duty factor is defined as the fraction of the IDT width spanned by the width of the IDT fingers in the direction of propagation of the main surface acoustic wave to be generated. Increasing the width of the IDT fingers, as shown in FIG. 8A, (while maintaining the position of the center of each IDT finger) increases the duty factor. Other fixed parameters used in the simulation are a thickness of the bottom layer in the IDT made of platinum of 0.025 λ, a thickness of the upper layer in the IDT made of aluminum of 0.04 λ, a top SiO₂ thickness equal to 0.4 λ, and a bottom SiO₂ thickness equal to 0.006 λ, where λ is the wavelength of the main acoustic wave generated by the interdigital transducer during operation. FIGS. 8B, 8C, 8D and 8E show the variation of the velocity of the main acoustic mode, TCF, k² and static capacitance respectively as DF changes.

As shown in FIG. 8B, the velocity of the main acoustic mode changes rapidly when DF is less than 0.5. When DF is greater than 0.5 the velocity of the main acoustic mode does not vary as much. In order to suppress transverse modes, a difference in the velocity is used. For example, as discussed above for the hammer head type IDT, the hammer portions (which have an increased DF in the edge portions E of the IDT) reduce the acoustic velocity in the edge portions E compared to the central portion C. This velocity reduction creates a piston mode distribution to reduce transverse modes. To obtain a large enough velocity difference for transverse mode suppression through a larger DF in the edge portions E, the DF of the central portion C of the IDT should be less than 0.5, where the velocity changes rapidly. Duty factor tuning is more difficult when the DF is above 0.5 due to the shallow gradient.

However, as shown in FIG. 8E, static capacitance decreases as the DF decreases. As mentioned, a smaller static capacitance leads to a larger size device for a given impedance, as static capacitance sets the limit on the IDT size. FIG. 8E shows the static capacitance as a percent of the static capacitance when the duty factor is 0.5. When DF is 0.4 the static capacitance is just 87% of the static capacitance when DF is 0.5. Therefore, although better for the velocity difference, a DF lower than 0.5 is worse for size reduction.

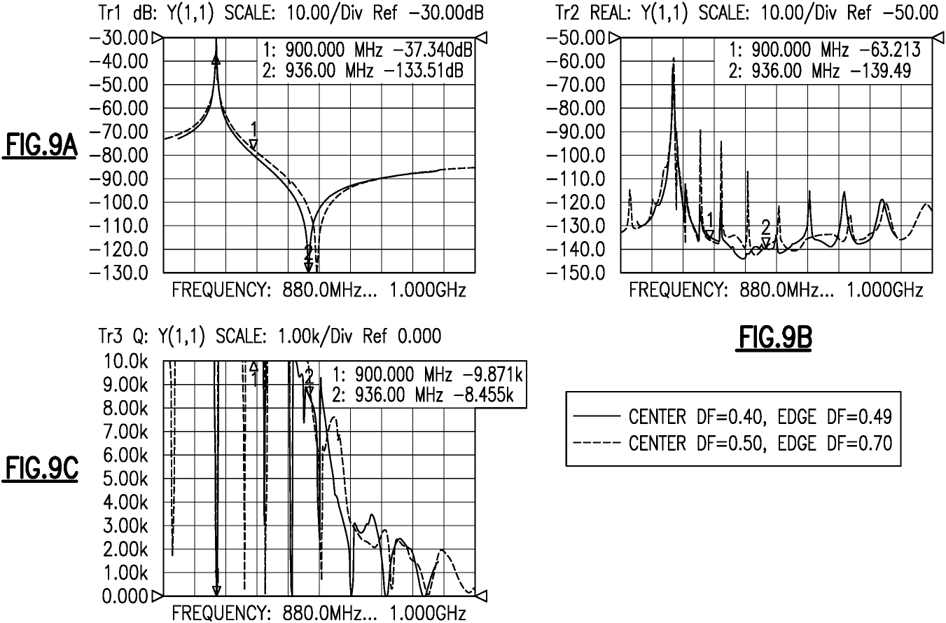

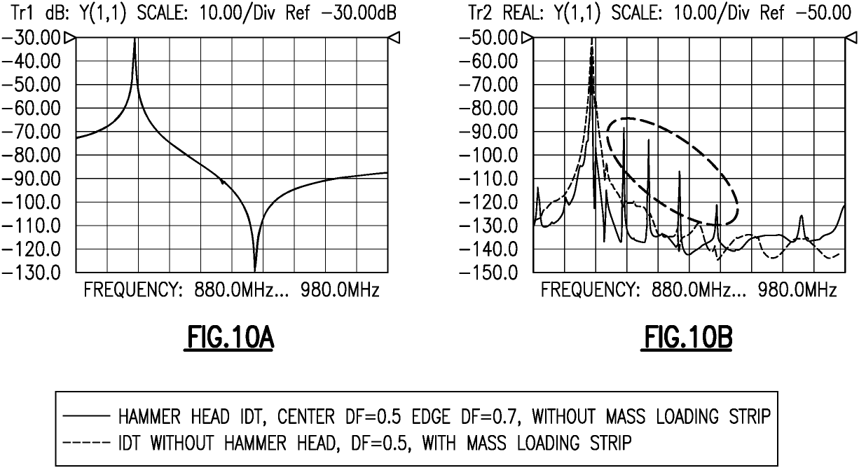

FIGS. 9A to 9C are simulation graphs showing a comparison between admittance curves (complex FIG. 9A, and real FIG. 9B) and Q-factor curves (FIG. 9C) of acoustic wave devices with a floating hammer head type IDT as disclosed herein. In FIGS. 9A to 9C the solid line is for an IDT with a DF of 0.4 in the central portions C, and a DF of 0.49 in the edge portions E, and the dashed line is for an IDT with a DF of 0.5 in the central portions C, and a DF of 0.7 in the edge portions E. No mass loading strips or cut out portions in the passivation layer are present.

As can be seen from FIGS. 9A to 9C, a central portion DF of 0.4 combined with a larger DF of 0.49 in the edge portions gives good transverse mode suppression, but will lead to a larger device because of the lower static capacitance due to the DF of 0.4. On the other hand, providing a central portion DF of 0.5 prevents an increase in size of the device, but makes it more difficult to suppress transverse modes due to the small velocity differential, even when a DF of 0.7 is used in the edge portions. Some transverse mode suppression does occur when a DF of 0.7 is used in the edge portions, and a DF of 0.5 used in the central portion, however the transverse modes can still be seen, particularly through the spikes in the dashed graph trace in FIG. 9B. Therefore, although possible in some embodiments, using a floating IDT with a hammer head structure alone to suppress the transverse modes can lead to either transverse modes not being fully suppressed, or an increase in size of the device. Therefore, it can be further beneficial to use the above described mass loading strips or cut out portions to suppress transverse modes, as set out below.

FIGS. 10A and 10B are simulation graphs showing a comparison between admittance curves (complex FIG. 10A, and real FIG. 10B) of acoustic wave devices with a floating hammer head type IDT as disclosed herein. In FIGS. 10A and 10B the solid line is for an IDT with a DF of 0.5 in the central portions C, and a DF of 0.7 in the edge portions E, and no mass loading strips or cut out portions in the passivation layer (the solid line in FIGS. 10A and 10B is therefore the same as the dashed line in FIGS. 9A and 9B). In FIGS. 10A and 10B the dashed line is for an IDT with a DF of 0.5 in both the central portions C and the edge portions E (therefore not a hammer head type IDT) and a pair of mass loading strips included the temperature compensation layer. The dashed line in FIGS. 10A and 10B corresponds to the embodiment of FIGS. 2A and 2B.

As can be seen in FIG. 10A the plots on the graph for each of the two devices almost entirely overlap. This shows that use of the mass loading strips 250 give similar characteristics as the hammer head type IDT with central DF of 0.5 and edge DF of 0.7. However, as seen in FIG. 10B, the transverse modes (highlighted in the dashed circle), are very effectively suppressed by the mass loading strips 250, even when the central DF is 0.5. Therefore, the mass loading strips 250 mean that any size increase because of a reduction in static capacitance due to a DF of less than 0.5 can be prevented, while still effectively suppressing the transverse modes.

FIGS. 11A and 11B are simulation graphs showing a comparison between admittance curves (complex FIG. 11A, and real FIG. 11B) of acoustic wave devices with a floating hammer head type IDT as disclosed herein. In FIGS. 11A and 11B the solid line is for an IDT with a DF of 0.5 in the central portions C, and a DF of 0.7 in the edge portions E, and no mass loading strips or cut out portions in the passivation layer (the solid line in FIGS. 11A and 11B is therefore the same as the dashed line in FIGS. 9A and 9B). In FIGS. 11A and 11B the dashed line is for an IDT with a DF of 0.5 in the central portions C, and a DF of 0.55 in the edge portions E, and a pair of cut out portions included the temperature passivation layer. The dashed line in FIGS. 11A and 11B corresponds to the embodiment combining FIGS. 3A and 3C. The cut out portions (SiN trenches) in the passivation layer of the present exemplary embodiment have a depth of 0.009 λ (36 nm).

As can be seen in FIG. 11A the plots on the graph for each of the two devices almost entirely overlap. This shows that use of the cut out portions 352 in the passivation layer give similar characteristics as the hammer head type IDT with central DF of 0.5 and edge DF of 0.7. However, as seen in FIG. 11B, the transverse modes are suppressed by the cut out portions 352, even when the central DF is 0.5. Therefore, the cut out portions 352 mean that any size increase because of a reduction in static capacitance due to a DF of less than 0.5 can be prevented, while still effectively suppressing the transverse modes.

Moreover, the cut out portions 352 can effectively suppress the transverse modes even when the DF of the edge portions is only 0.55, with a DF of 0.5 in the central portion. A DF of 0.55 is more acceptable from a manufacturing point of view, as a DF of 0.7 can be challenging to manufacture industrially.

In summary, the mass loading strips and cut out portions discussed above in relation to FIGS. 10A to 11C can further suppress transverse modes over the suppression due to the spatial separation between the IDT and piezoelectric substrate, without having to reduce the DF of the IDT to below 0.5 causing a corresponding decrease in static capacitance and increase in size. The floating IDT and mass loading strip/cut out portion combination of the present embodiments gives an acoustic wave device a good TCF, good Q-factor, small transverse mode spurious signals, and a large k² due to the low cut LN piezoelectric substrate. The mass loading strips can be effectively combined with a simpler type IDT without hammer head, which can simplify manufacturing. The cut out portions can be effectively used with a DF of 0.55 in the edge portions, which is also easier to manufacture compared to a DF of 0.7.

The various embodiments described above provide acoustic wave devices for wide passband applications which have excellent temperature coefficients of frequency, large k², and clean (transverse mode suppressed) responses, as well as having a small size.

The embodiments of the acoustic wave device disclosed herein may be used in various different applications. In general, the acoustic wave device may be used in any device that includes an IDT. For example, the acoustic wave device may be used in various types of acoustic wave resonators and/or filters, including 1-port resonators, 2-port resonators, ladder filters, and the like. In a resonator configuration, one or more reflector electrodes may be included surrounding/sandwiching the IDT. Although the embodiments above have been described with only one IDT within the temperature compensation layer, other configurations are possible, as would be understood by the skilled person.

It should be appreciated that the various embodiments of acoustic wave devices illustrated in the figures, as well as the other circuit elements illustrated in other figures presented herein, are illustrated in a highly simplified form. The relative dimensions of the different features are not shown to scale. Further, typical acoustic wave devices would commonly include a far greater number of electrode fingers in the IDTs than illustrated.

The concepts and embodiments of acoustic wave devices described herein are applicable to various types of devices, as would be understood by the skilled person. For example, the aspects and embodiments disclosed herein may be applied to filters, duplexers, diplexers or the like, no matter what materials are used in the piezoelectric substrate, temperature compensation layer, IDT and passivation layer. The reduction in side leakage and the suppression of transverse modes in the above described acoustic wave devices may lead to an overall improvement in the overall functioning of the circuit. The small size of the above described acoustic wave devices may allow more devices to be formed per given amount of area in a circuit having a certain number of acoustic wave devices, leading to an overall reduction in size of the circuit.

For example, FIG. 12 shows an example of a SAW filter 700 which multiple acoustic wave devices as disclosed herein may be combined. FIG. 12 shows an RF ladder filter 700 including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW or TC-SAW devices or resonators, for example, duplexers, baluns, etc., may also be formed including examples of acoustic wave devices as disclosed herein.

Moreover, examples and embodiments of acoustic wave devices discussed herein can be implemented in a variety of packaged modules. Some example packaged modules will now be discussed in which any suitable principles and advantages of the acoustic wave devices discussed herein can be implemented. FIGS. 13, 14, and 15 are schematic block diagrams of illustrative packaged modules and devices according to certain embodiments.

As discussed above, acoustic wave devices, such as those of FIGS. 2A to 3D, can be used in radio frequency (RF) filters. In turn, an RF filter such as the SAW filter of FIG. 12, may be incorporated into and packaged as a module that may ultimately be used in an electronic device, such as a wireless communications device, for example. FIG. 13 is a block diagram illustrating one example of a module 815 including a SAW filter 800. The SAW filter 800 may be implemented on one or more die(s) 825 including one or more connection pads 822. For example, the SAW filter 800 may include a connection pad 822 that corresponds to an input contact for the SAW filter and another connection pad 822 that corresponds to an output contact for the SAW filter. The packaged module 815 includes a packaging substrate 830 that is configured to receive a plurality of components, including the die 825. A plurality of connection pads 832 can be disposed on the packaging substrate 830, and the various connection pads 822 of the SAW filter die 825 can be connected to the connection pads 832 on the packaging substrate 830 via electrical connectors 834, which can be solder bumps or wirebonds, for example, to allow for passing of various signals to and from the SAW filter 800. The module 815 may optionally further include other circuitry die 840, for example, one or more additional filter(s), amplifiers, pre-filters, modulators, demodulators, down converters, and the like, as would be known to one of skill in the art of semiconductor fabrication in view of the disclosure herein. In some embodiments, the module 815 can also include one or more packaging structures to, for example, provide protection and facilitate easier handling of the module 815. Such a packaging structure can include an overmold formed over the packaging substrate 830 and dimensioned to substantially encapsulate the various circuits and components thereon.

Various examples and embodiments of the SAW filter 800 can be used in a wide variety of electronic devices. For example, the SAW filter 800 can be used in an antenna duplexer, which itself can be incorporated into a variety of electronic devices, such as RF front-end modules and communication devices.

Referring to FIG. 14, there is illustrated a block diagram of one example of a front-end module 900, which may be used in an electronic device such as a wireless communications device (e.g., a mobile phone) for example. The front-end module 900 includes an antenna duplexer 910 having a common node 902, an input node 904, and an output node 906. An antenna 1010 is connected to the common node 902.

The antenna duplexer 910 may include one or more transmission filters 912 connected between the input node 904 and the common node 902, and one or more reception filters 914 connected between the common node 902 and the output node 906. The passband(s) of the transmission filter(s) are different from the passband(s) of the reception filters. Examples of the SAW filter 800 can be used to form the transmission filter(s) 912 and/or the reception filter(s) 914. An inductor or other matching component 920 may be connected at the common node 902.

The front-end module 900 further includes a transmitter circuit 932 connected to the input node 904 of the duplexer 910 and a receiver circuit 934 connected to the output node 906 of the duplexer 910. The transmitter circuit 932 can generate signals for transmission via the antenna 1010, and the receiver circuit 934 can receive and process signals received via the antenna 1010. In some embodiments, the receiver and transmitter circuits are implemented as separate components, as shown in FIG. 14, however, in other embodiments these components may be integrated into a common transceiver circuit or module. As will be appreciated by those skilled in the art, the front-end module 900 may include other components that are not illustrated in FIG. 14 including, but not limited to, switches, electromagnetic couplers, amplifiers, processors, and the like.

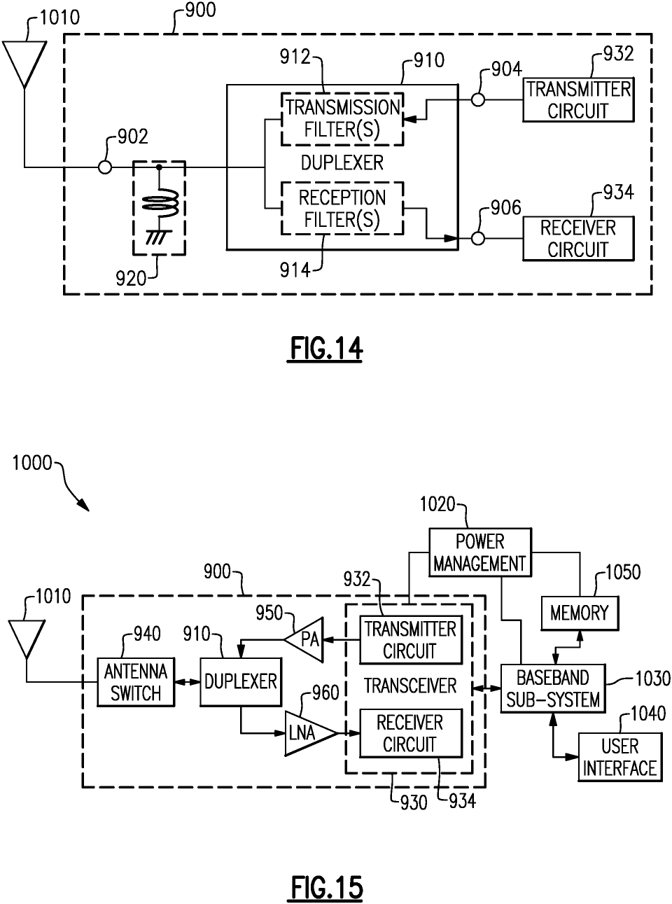

FIG. 15 is a block diagram of one example of a wireless device 1000 including the antenna duplexer 910 shown in FIG. 14. The wireless device 1000 can be a cellular phone, smart phone, tablet, modem, communication network or any other portable or non-portable device configured for voice or data communication. The wireless device 1000 can receive and transmit signals from the antenna 1010. The wireless device includes an embodiment of a front-end module 900 similar to that discussed above with reference to FIG. 14. The front-end module 900 includes the duplexer 910, as discussed above. In the example shown in FIG. 15 the front-end module 900 further includes an antenna switch 940, which can be configured to switch between different frequency bands or modes, such as transmit and receive modes, for example. In the example illustrated in FIG. 15, the antenna switch 940 is positioned between the duplexer 910 and the antenna 1010; however, in other examples the duplexer 910 can be positioned between the antenna switch 940 and the antenna 1010. In other examples the antenna switch 940 and the duplexer 910 can be integrated into a single component.

The front-end module 900 includes a transceiver 930 that is configured to generate signals for transmission or to process received signals. The transceiver 930 can include the transmitter circuit 932, which can be connected to the input node 904 of the duplexer 910, and the receiver circuit 934, which can be connected to the output node 906 of the duplexer 910, as shown in the example of FIG. 14.

Signals generated for transmission by the transmitter circuit 932 are received by a power amplifier (PA) module 950, which amplifies the generated signals from the transceiver 930. The power amplifier module 950 can include one or more power amplifiers. The power amplifier module 950 can be used to amplify a wide variety of RF or other frequency-band transmission signals. For example, the power amplifier module 950 can receive an enable signal that can be used to pulse the output of the power amplifier to aid in transmitting a wireless local area network (WLAN) signal or any other suitable pulsed signal. The power amplifier module 950 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 950 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 15, the front-end module 900 may further include a low noise amplifier (LNA) module 960, which amplifies received signals from the antenna 1010 and provides the amplified signals to the receiver circuit 934 of the transceiver 930.

The wireless device 1000 of FIG. 15 further includes a power management sub-system 1020 that is connected to the transceiver 930 and manages the power for the operation of the wireless device 1000. The power management system 1020 can also control the operation of a baseband sub-system 1030 and various other components of the wireless device 1000. The power management system 1020 can include, or can be connected to, a battery (not shown) that supplies power for the various components of the wireless device 1000. The power management system 1020 can further include one or more processors or controllers that can control the transmission of signals, for example. In one embodiment, the baseband sub-system 1030 is connected to a user interface 1040 to facilitate various input and output of voice and/or data provided to and received from the user. The baseband sub-system 1030 can also be connected to memory 1050 that is configured to store data and/or instructions to facilitate the operation of the wireless device, and/or to provide storage of information for the user.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. An acoustic wave device, comprising:
a piezoelectric substrate;
a temperature compensation layer disposed on the piezoelectric substrate;
an interdigital transducer embedded within the temperature compensation layer and spatially separated from the piezoelectric substrate, the interdigital transducer including a pair of interdigital transducer electrodes, each electrode having a bus bar and a plurality of fingers extending from the bus bar towards the bus bar of the other electrode, the interdigital transducer being configured to generate a main acoustic wave in response to an electrical signal; and
a passivation layer disposed on the temperature compensation layer.

2. The acoustic wave device of claim 1 wherein the separation between the interdigital transducer and the piezoelectric substrate is between about 0.002 λ and 0.01 λ, where λ is the wavelength of the main acoustic wave generated by the interdigital transducer during operation.

3. The acoustic wave device of claim 1 wherein the separation between the interdigital transducer and a top surface of the temperature compensation layer is between about 0.3 λ, and 0.4 λ, where λ is the wavelength of the main acoustic wave generated by the interdigital transducer during operation.

4. The acoustic wave device of claim 3 wherein the fingers of each interdigital transducer electrode interleave with one another in a first region of the interdigital transducer and form a gap region between the ends of the fingers of one of the electrodes and the bus bar of the other electrode, the first region including a central portion and two edge portions, each edge portion extending from the tips of the plurality of fingers of one of the electrodes towards the center of the central portion.

5. The acoustic wave device of claim 4 wherein a duty factor of the interdigital transducer electrodes in the edge portions of the first region is greater than the duty factor of the interdigital transducer electrodes in the central portion of the first region.

6. The acoustic wave device of claim 4 further comprising a suppression element configured to suppress a transverse mode of the interdigital transducer.

7. The acoustic wave device of claim 6 wherein the suppression element is a pair of cut out portions in the passivation layer.

8. The acoustic wave device of claim 7 wherein the pair of cut out portions each overlap a respective one of the edge portions of the first region of the interdigital transducer.

9. The acoustic wave device of claim 7 wherein the pair of cut out portions each extend in a direction parallel to the bus bars of the interdigital transducer along the length of the interdigital transducer.

10. The acoustic wave device of claim 7 wherein the pair of cut out portions each have a width in a direction parallel to the fingers of the interdigital transducer electrodes of between about 0.5 λ, and 1.5 λ, where λ is the wavelength of the main acoustic wave generated by the interdigital transducer during operation.

11. The acoustic wave device of claim 7 wherein the pair of cut out portions extend in a direction parallel to the fingers of the interdigital transducer electrodes up to an outer edge of the acoustic wave device.

12. The acoustic wave device of claim 7 wherein the pair of cut out portions each have depth of between about 0.005 λ, and 0.04 λ, where λ is the wavelength of the main acoustic wave generated by the interdigital transducer during operation.

13. The acoustic wave device of claim 7 wherein the thickness of the passivation layer is largest in the region overlapping the central portion of the first region of the interdigital transducer.

14. The acoustic wave device of claim 6 wherein the suppression element is a pair of mass loading strips embedded within the temperature compensation layer.

15. The acoustic wave device of claim 14 wherein the pair of mass loading strips each overlap a respective one of the edge portions of the first region of the interdigital transducer.

16. The acoustic wave device of claim 14 wherein the pair of mass loading strips each extend in a direction parallel to the bus bars of the interdigital transducer along the length of the interdigital transducer.

17. The acoustic wave device of claim 14 wherein the pair of mass loading strips each have a width in a direction parallel to the fingers of the interdigital transducer electrodes of between about 0.5 λ and 1.5 λ, where λ is the wavelength of the main acoustic wave generated by the interdigital transducer during operation.

18. The acoustic wave device of claim 14 wherein the pair of mass loading strips each have a thickness of between about 0.005 λ, and 0.04 λ, where λ is the wavelength of the main acoustic wave generated by the interdigital transducer during operation.

19. The acoustic wave device of claim 14 wherein the pair of mass loading strips are formed from a conductive material.

20. The acoustic wave device of claim 14 wherein the pair of mass loading strips are formed from a material with a higher density than a density of the temperature compensation layer.

21. The acoustic wave device of claim 6 wherein the suppression element is formed from a pair of hammer portions in each of the plurality of fingers, each of the hammer portions being located in a respective one of the edge portions of the first region of the interdigital transducer, and each having a width larger than the width of each finger in the central portion of the first region of the interdigital transducer.

22. The acoustic wave device of claim 21 wherein a duty factor of the interdigital transducer electrodes in the edge portions of the first region is greater than the duty factor of the interdigital transducer electrodes in the central portion of the first region.

23. The acoustic wave device of claim 21 wherein each of the interdigital transducer electrodes includes a second bus bar that is located within the gap region.

24. The acoustic wave device of claim 23 wherein each of the second bus bars includes one or more gaps positioned along the length of the second bus bars.

25. The acoustic wave device of claim 6 wherein the suppression element includes at least one of a mass loading strip embedded within the temperature compensation layer, a cut out portion in the passivation layer, or hammer portions in each of the plurality of fingers, the hammer portions having a width larger than the width of each finger away from the hammer portion.

26. An acoustic wave device, comprising:
a piezoelectric substrate;
a temperature compensation layer disposed on the piezoelectric substrate; and
an interdigital transducer disposed within the temperature compensation layer and spatially separated from the piezoelectric substrate, the interdigital transducer being configured to generate an acoustic wave in response to an electrical signal.

27. An electronics module comprising at least one radio frequency filter that includes at least one acoustic wave device, the at least one acoustic wave device including:
a piezoelectric substrate;
a temperature compensation layer disposed on the piezoelectric substrate;
an interdigital transducer embedded within the temperature compensation layer and spatially separated from the piezoelectric substrate, the interdigital transducer being configured to generate an acoustic wave in response to an electrical signal; and
a passivation layer disposed on the temperature compensation layer.
